(19) United States
(12) Patent Application Publication
(10) Pub. No.: US 2021/0309234 A1
(43) Pub. Date: Oct. 7, 2021

(54) INFORMATION PROCESSING APPARATUS, INFORMATION PROCESSING METHOD, AND INFORMATION PROCESSING PROGRAM

(71) Applicant: NEC Corporation, Minato-ku, Tokyo (JP)

(72) Inventor: Jun NAKAYAMADA, Tokyo (JP)

(73) Assignee: NEC Corporation, Minato-ku, Tokyo (JP)

(21) Appl. No.: 17/265,037

(22) PCT Filed: Sep. 14, 2018
(86) PCT No.: PCT/JP2018/034164

§ 371 Date: Feb. 1, 2021

(30) Foreign Application Priority Data
Aug. 3, 2018 (JP) 2018-146727

(51) Int. Cl. B60W 50/00; G08G 1/01

(52) U.S. Cl. CPC B60W 50/0097; G08G 1/0133; G08G 1/012

(57) ABSTRACT

Data in a pre-dangerous state of a vehicle that is difficult to generate in an actual environment is collected efficiently. There is provided an information processing apparatus including a traveling instructor that instructs virtual traveling while providing traveling parameters to a traveling simulator that simulates traveling of at least one virtual peripheral vehicle and a virtual self-vehicle in a virtual environment, and a detector that detects occurrence of a dangerous state for the self-vehicle in the simulation by the traveling simulator.

This application is based upon and claims the benefit of priority from Japanese patent application No. 2018-146727, filed on Aug. 3, 2018, the disclosure of which is incorporated herein in its entirety by reference.

### TECHNICAL FIELD

The present invention relates to an information processing apparatus, an information processing method, and an information processing program.

### BACKGROUND ART

In the above technical field, patent literature 1 discloses a technique of generating a plurality of images from a source image by a simulation, and displaying a determination result by machine learning and parameters concerning the simulation in association with each other.

### CITATION LIST

### Patent Literature

Patent literature 1: International Publication No. 2017/168898

### SUMMARY OF THE INVENTION

### Technical Problem

In the technique described in the above literature, however, it is impossible to efficiently collect data in a pre-dangerous state of a vehicle that is difficult to generate in an actual environment.

The present invention provides a technique of solving the above-described problem.

### Solution to Problem

One example aspect of the present invention provides an information processing apparatus comprising:

a traveling instructor that instructs virtual traveling while providing traveling parameters to a traveling simulator that simulates traveling of at least one virtual peripheral vehicle and a virtual self-vehicle in a virtual environment; and

a detector that detects occurrence of a dangerous state for the self-vehicle in the simulation by the traveling simulator.

Another example aspect of the present invention provides an information processing method, comprising:

instructing virtual traveling while providing traveling parameters to a traveling simulator that simulates traveling of at least one virtual peripheral vehicle and a virtual self-vehicle in a virtual environment; and

detecting occurrence of a dangerous state for the self-vehicle in the simulation by the traveling simulator.

Still other example aspect of the present invention provides an information processing program for causing a computer to execute a method, comprising:

instructing virtual traveling while providing traveling parameters to a traveling simulator that simulates traveling of at least one virtual peripheral vehicle and a virtual self-vehicle in a virtual environment; and

detecting occurrence of a dangerous state for the self-vehicle in the simulation by the traveling simulator.

### Advantageous Effects of Invention

According to the present invention, it is possible to efficiently collect data in a pre-dangerous state of a vehicle that is difficult to generate in an actual environment.

### BRIEF DESCRIPTION OF DRAWINGS

FIG. 1 is a block diagram showing the arrangement of an information processing apparatus according to the first example embodiment of the present invention;

FIG. 2 is a view for explaining an overview of the operation of an information processing apparatus according to the second example embodiment of the present invention;

FIG. 3 is a block diagram showing the arrangement of the information processing apparatus according to the second example embodiment of the present invention;

FIG. 4 is a table showing an example of a parameter table provided in the information processing apparatus according to the second example embodiment of the present invention;

FIG. 5 is a block diagram showing the hardware arrangement of the information processing apparatus according to the second example embodiment of the present invention;

FIG. 6 is a flowchart for explaining the processing procedure of the information processing apparatus according to the second example embodiment of the present invention;

FIG. 7 is a block diagram showing the arrangement of an information processing apparatus according to the third example embodiment of the present invention;

FIG. 8 is a table showing an example of a parameter table provided in the information processing apparatus according to the third example embodiment of the present invention;

FIG. 9 is a block diagram showing the hardware arrangement of the information processing apparatus according to the third example embodiment of the present invention;

FIG. 10 is a flowchart for explaining the processing procedure of the information processing apparatus according to the third example embodiment of the present invention;

FIG. 11 is a view for explaining an example of the display screen of an information processing apparatus according to the fourth example embodiment of the present invention;

FIG. 12 is a block diagram showing the arrangement of the information processing apparatus according to the fourth example embodiment of the present invention; and

FIG. 13 is a table showing an example of a classification table provided in the information processing apparatus according to the fourth example embodiment of the present invention.

### DESCRIPTION OF EXAMPLE EMBODIMENTS

Example embodiments of the present invention will now be described in detail with reference to the drawings. It should be noted that the relative arrangement of the components, the numerical expressions and numerical values set forth in these example embodiments do not limit the scope of the present invention unless it is specifically stated otherwise.

### First Example Embodiment

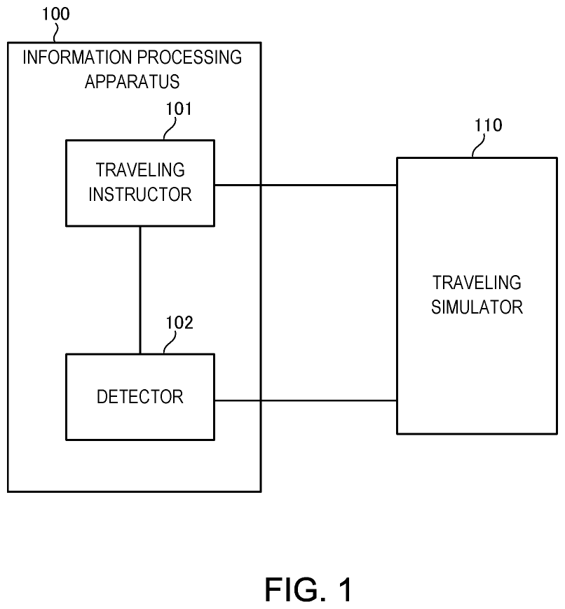

An information processing apparatus 100 according to the first example embodiment of the present invention will be described with reference to FIG. 1. The information processing apparatus 100 is an apparatus that simulates traveling of a self-vehicle in a virtual environment.

As shown in FIG. 1, the information processing apparatus 100 includes a traveling instructor 101 and a detector 102.

The traveling instructor 101 instructs virtual traveling while providing traveling parameters to a traveling simulator 110 that simulates traveling of at least one virtual peripheral vehicle and a virtual self-vehicle in a virtual environment. The detector 102 detects the occurrence of a dangerous state for the self-vehicle in the simulation by the traveling simulator 110.

According to this example embodiment, it is possible to efficiently collect data in a pre-dangerous state of a vehicle that is difficult to generate in an actual environment.

### Second Example Embodiment

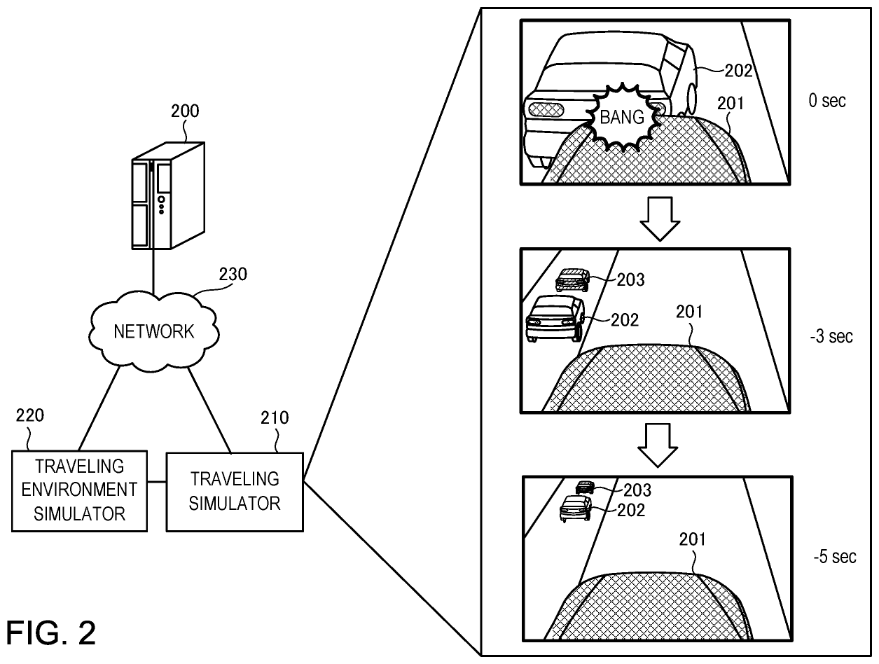

An information processing apparatus according to the second example embodiment of the present invention will be described next with reference to FIGS. 2 to 10. FIG. 2 is a view for explaining an overview of the operation of the information processing apparatus according to this example embodiment. An information processing apparatus 200 is connected to a traveling simulator 210 and a traveling environment simulator 220 via a network 230. The information processing apparatus 200 instructs virtual traveling while providing traveling parameters of a self-vehicle 201 and peripheral vehicles 202 and 203 to the traveling simulator 210. The information processing apparatus 200 also instructs a simulation of a traveling environment while providing traveling environment parameters to the traveling environment simulator 220. The traveling environment simulator 220 passes the simulation of the traveling environment to the traveling simulator 210. Upon receiving the simulation of the traveling environment, the traveling simulator 210 executes a traveling simulation of the self-vehicle 201 and the peripheral vehicles 202 and 203 in the received traveling environment. Note that there are two peripheral vehicles 202 and 203 in this example but the number of peripheral vehicles is not limited to this and there may be three or more peripheral vehicles.

The information processing apparatus 200 detects the occurrence of a dangerous state for the self-vehicle 201 using a predetermined index based on the simulation executed by the traveling simulator 210. If the dangerous state is detected, the information processing apparatus 200 acquires, from the traveling simulator 210, determination information for determining that the self-vehicle is in a pre-dangerous state before the detected dangerous state is generated, and accumulates the determination information.

As shown in FIG. 2, if the self-vehicle 201 collides from behind with the peripheral vehicle 202, which has changed the lane in front of the self-vehicle 201 (0 sec), the information processing apparatus 200 determines that the self-vehicle 201 is put in a dangerous state. Then, the information processing apparatus 200 extracts pieces of determination information respectively predetermined periods, for example, 3 sec (−3 sec) and 5 sec (−5 sec) before the self-vehicle 201 is put in the dangerous state (0 sec), and accumulates them. Note that the predetermined period is a predetermined time before the dangerous state but is not limited to this, and may be a predetermined number of frames before the dangerous state.

The information processing apparatus 200 updates the traveling parameters and the traveling environment parameters when the self-vehicle 201 is put in the dangerous state, and provides the updated parameters to the traveling simulator 210 and the traveling environment simulator 220, thereby instructing to execute virtual traveling.

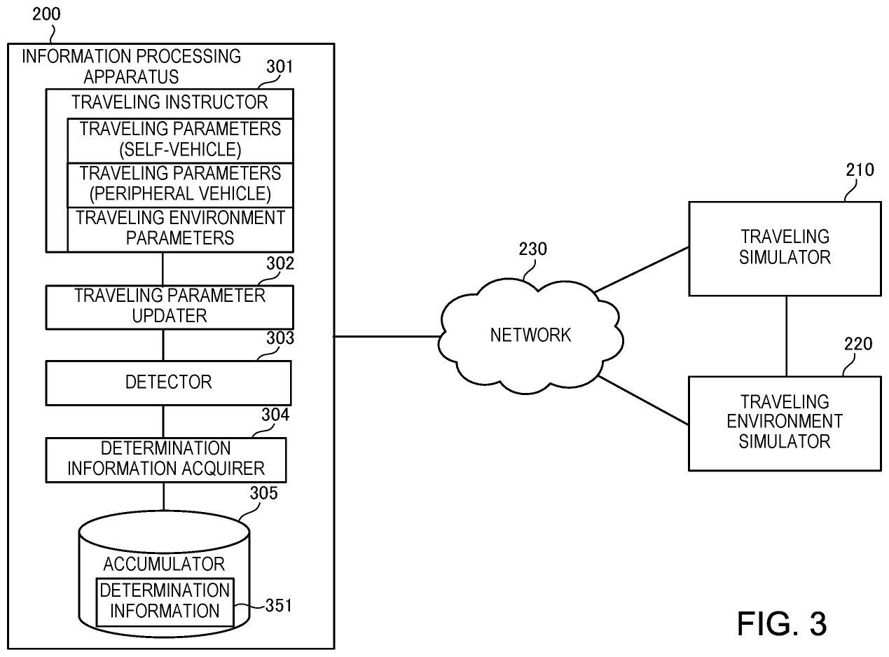

FIG. 3 is a block diagram showing the arrangement of the information processing apparatus 200 according to this example embodiment. The information processing apparatus 200 includes a traveling instructor 301, a traveling parameter updater 302, a detector 303, a determination information acquirer 304, and an accumulator 305. Note that as shown in FIG. 3, the traveling simulator 210 may be a component outside the information processing apparatus 200 or may be included in the arrangement of the information processing apparatus 200.

The traveling instructor 301 provides self-vehicle traveling parameters and peripheral vehicle traveling parameters to the traveling simulator 210. The traveling instructor 301 instructs the traveling simulator 210 to execute virtual traveling of the self-vehicle 201 and the peripheral vehicles 202 and 203. The self-vehicle traveling parameters and peripheral vehicle traveling parameters (traveling parameters) include, for example, a speed, a position, a brake operation amount, and the rotation angular velocity of the steering wheel but are not limited to them.

The traveling instructor 301 instructs the traveling environment simulator 220 to generate a virtual traveling environment, and instructs a simulation of the traveling environment while providing the traveling environment parameters. Upon receiving the traveling environment parameters provided from the traveling instructor 301, the traveling environment simulator 220 passes the simulation of the generated traveling environment to the traveling simulator 210. The traveling environment parameters include, for example, a road type such as a highway, a general road, or a one-way road, an obstacle such as a traffic signal or a utility pole, and a pedestrian, but are not limited to them.

The traveling simulator 210 simulates traveling of the self-vehicle 201 and the peripheral vehicles 202 and 203 in the traveling environment generated by the traveling environment simulator 220.

The traveling instructor 301 provides, to the traveling simulator 210, the peripheral vehicle traveling parameters of the peripheral vehicles 202 and 203 that readily generate a dangerous state. This can generate, in a virtual environment, a dangerous state for the self-vehicle 201, that cannot be generated in an actual environment.

The traveling parameter updater 302 updates the self-vehicle traveling parameters, the peripheral vehicle traveling parameters, and the traveling environment parameters provided by the traveling instructor 301. The traveling instructor 301 provides the updated self-vehicle traveling parameters, peripheral vehicle traveling parameters, and traveling environment parameters to the traveling simulator 210 and the traveling environment simulator 220.

The traveling parameter updater 302 updates the parameters by slightly shifting, backward/forward, the parameters, mainly the peripheral vehicle traveling parameters and traveling environment parameters that have generated the dangerous state. This can comprehensively simulate a situation in which the dangerous state occurs.

The detector 303 detects the occurrence of the dangerous state for the self-vehicle 201 in the simulation executed by the traveling simulator 210. The dangerous state is detected by, for example, calculating a dangerous state index. The dangerous state index is, for example, TTC (Time To Collision) but is not limited to this. The dangerous state index may be, for example, PICUD (Possibility Index for Collision with Urgent Deceleration), PET (Post Encroachment Time), or PTTC (Potential Time to Collision). Then, if the dangerous state index satisfies a predetermined condition, the detector 303 determines the dangerous state. If TTC is used as the dangerous state index, the predetermined condition is, for example, 0≤TTC<1 but is not limited to this. Then, the traveling instructor 301 changes some of the traveling parameters in one dangerous state detected by the detector 303, which are associated with the detected dangerous state. That is, when a given dangerous state is detected, the traveling instructor 301 changes some of the traveling parameters, which are associated with the detected dangerous state so as to simulate all over the periphery of the pre-dangerous state, instead of updating (changing) all the traveling parameters randomly. If all the traveling parameters are updated randomly, no pre-dangerous state may occur, and the simulation is useless. To prevent a useless simulation and intensively, efficiently execute a simulation, the traveling instructor 301 changes some of the traveling parameters, which are associated with the detected dangerous state.

The determination information acquirer 304 acquires, from the traveling simulator 210, determination information a predetermined period, for example, a predetermined time or a predetermined number of frames before the dangerous state detected by the detector 303 is generated. The determination information acquirer 304 may acquire, from the traveling simulator 210, determination information from a period before a predetermined period until the dangerous state is generated.

The accumulator 305 accumulates acquired determination information 351. The accumulator 305 adds a time stamp and the like to the determination information 351 to be accumulated, and then accumulates the determination information 351. The determination information 351 includes, for example, a moving image or a still image captured by the dashcam or the like of the self-vehicle 201, and the speeds and positions of the self-vehicle 201 and the peripheral vehicles 202 and 203, but is not limited to them.

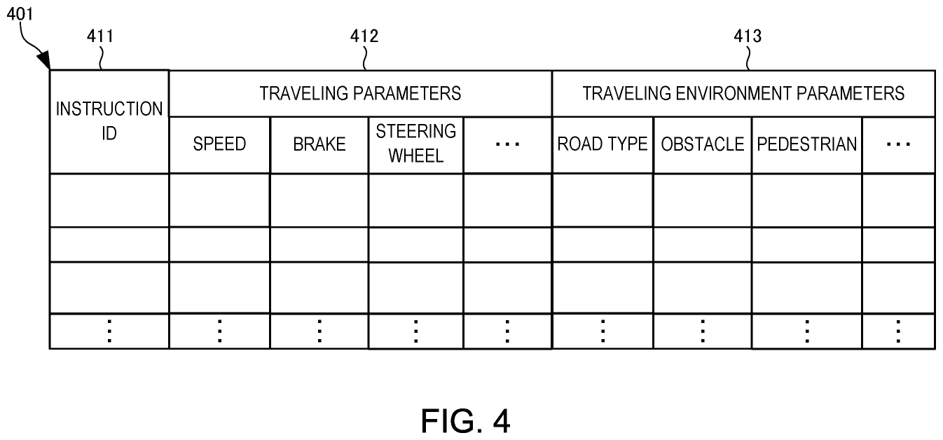

FIG. 4 is a table showing an example of a parameter table 401 provided in the information processing apparatus 200 according to this example embodiment. The parameter table 401 stores traveling parameters 412 and traveling environment parameters 413 in association with an instruction ID (IDentifier) 411. The instruction ID 411 is an identifier for identifying an instruction. The traveling parameters 412 are parameters for simulating traveling of the self-vehicle 201 and the peripheral vehicles 202 and 203 in a virtual environment. The traveling environment parameters 413 are parameters associated with the environment in which the self-vehicle 201 and the peripheral vehicles 202 and 203 travel, and parameters associated with a road type, an obstacle, a pedestrian, and the like. Then, the information processing apparatus 200 provides the traveling parameters and the traveling environment parameters to the traveling simulator 210 and the traveling environment simulator 220 with reference to, for example, the parameter table 401.

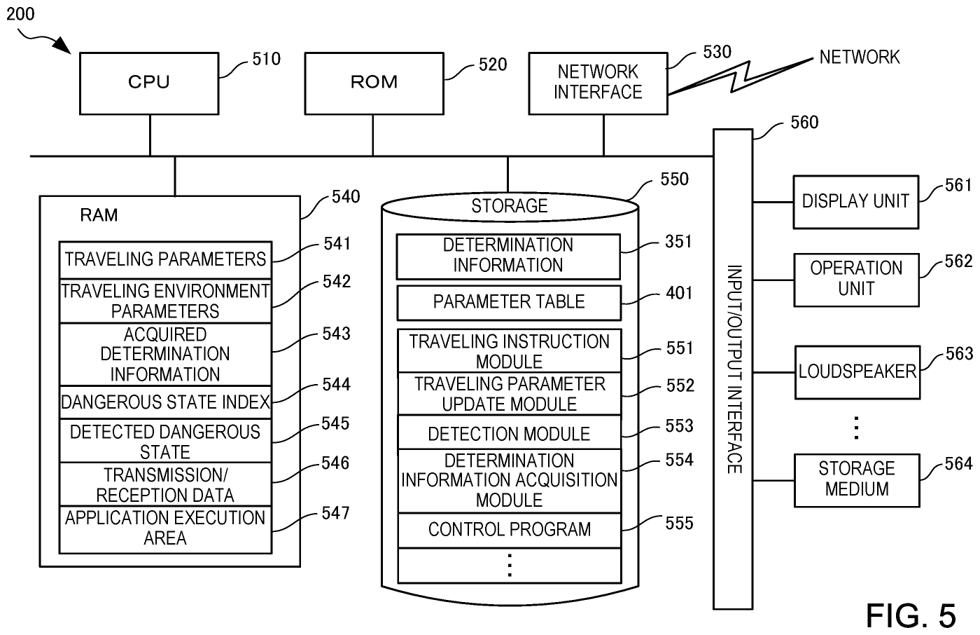

FIG. 5 is a block diagram for explaining the hardware arrangement of the information processing apparatus 200 according to this example embodiment. A CPU (Central Processing Unit) 510 is an arithmetic control processor, and implements the functional components of the information processing apparatus 200 shown in FIG. 3 by executing a program. The CPU 510 may include a plurality of processors to parallelly execute different programs, modules, tasks, or threads. A ROM (Read Only Memory) 520 stores permanent data such as initial data and a program, and other programs. A network interface 530 communicates with another apparatus or the like via a network. Note that the number of CPUs 510 is not limited to one, and a plurality of CPUs or a GPU (Graphics Processing Unit) for image processing may be included. The network interface 530 desirably includes a CPU independent of the CPU 510, and writes or reads transmission/reception data in or from the area of a RAM (Random Access Memory) 540. It is desirable to provide a DMAC (Direct Memory Access Controller) (not shown) for transferring data between the RAM 540 and a storage 550. Furthermore, the CPU 510 recognizes that data has been received by the RAM 540 or transferred to the RAM 540, and processes the data. The CPU 510 prepares a processing result in the RAM 540, and delegates succeeding transmission or transfer to the network interface 530 or the DMAC.

The RAM 540 is a random access memory used as a temporary storage work area by the CPU 510. An area to store data necessary for implementation of this example embodiment is allocated to the RAM 540. Traveling parameters 541 are parameters for simulating traveling of the self-vehicle 201 and the peripheral vehicles 202 and 203 in a virtual environment. Traveling environment parameters 542 are parameters associated with the environment in which the self-vehicle 201 and the peripheral vehicles 202 and 203 travel in the virtual environment. Acquired determination information 543 is information for determining whether the self-vehicle 201 is put in a dangerous state, as a result of a simulation by the traveling simulator 210. A dangerous state index 544 is an index used to determine the dangerous state from the acquired determination information 351. A detected dangerous state 545 is a dangerous state detected using the dangerous state index for determining the dangerous state.

Transmission/reception data 546 is data transmitted/received via the network interface 530. The RAM 540 includes an application execution area 547 for executing various application modules.

The storage 550 stores a database, various parameters, or the following data or programs necessary for implementation of this example embodiment. The storage 550 stores the determination information 351 and the parameter table 401. The parameter table 401 is the table, shown in FIG. 4, for managing the relationship among the instruction ID, the traveling parameters, and the traveling environment parameters.

The storage 550 further stores a traveling instruction module 551, a traveling parameter update module 552, a detection module 553, and a determination information acquisition module 554. The traveling instruction module 551 is a module that instructs virtual traveling while providing the self-vehicle traveling parameters, the peripheral vehicle traveling parameters, and the traveling environment parameters to the traveling simulator 210 and the traveling environment simulator 220. The traveling parameter update module 552 is a module that updates the self-vehicle traveling parameters, the peripheral vehicle traveling parameters, and the traveling environment parameters to be provided to the traveling simulator 210 and the traveling environment simulator 220. The detection module 553 is a module that detects the occurrence of a dangerous state for the self-vehicle 201. The determination information acquisition module 554 is a module that acquires, from the traveling simulator 210, determination information for determining a pre-dangerous state before the detected dangerous state is generated. These modules 551 to 554 are read out by the CPU 510 into the application execution area 547 of the RAM 540, and executed. A control program 555 is a program for controlling the whole information processing apparatus 200.

An input/output interface 560 interfaces input/output data with an input/output device. The input/output interface 560 is connected to a display unit 561 and an operation unit 562. In addition, a storage medium 564 may be connected to the input/output interface 560. A loudspeaker 563 serving as a voice output unit, a microphone (not shown) serving as a voice input unit, or a GPS position determiner may also be connected. Note that programs and data which are associated with the general-purpose functions of the information processing apparatus 200 and other feasible functions are not shown in the RAM 540 or the storage 550 of FIG. 5.

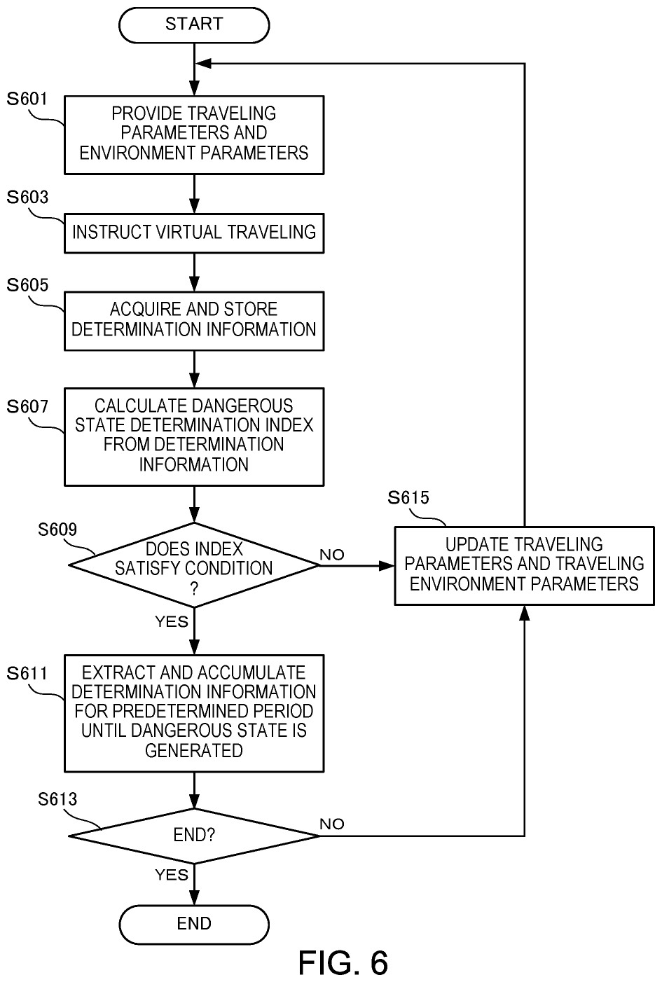

FIG. 6 is a flowchart for explaining the processing procedure of the information processing apparatus 200 according to this example embodiment. This flowchart is executed by the CPU 510 of FIG. 5 using the RAM 540, thereby implementing the functional components of the information processing apparatus 200 shown in FIG. 3.

In step S601, the information processing apparatus 200 provides the self-vehicle traveling parameters, the peripheral vehicle traveling parameters, and the traveling environment parameters to the traveling simulator 210 and the traveling environment simulator 220. In step S603, the information processing apparatus 200 instructs the traveling simulator 210 and the traveling environment simulator 220 to execute virtual traveling. In step S605, the information processing apparatus 200 acquires determination information from the traveling simulator 210, and stores it.

In step S607, the information processing apparatus 200 calculates a dangerous state determination index for determining a dangerous state from the acquired determination information. The calculated dangerous state determination index is, for example, TTC (Time To Collision) but is not limited to this. In step S609, the information processing apparatus 200 determines whether the dangerous state determination index satisfies a predetermined condition. The predetermined condition is, for example, 0≤TTC<1 but is not limited to this. If the dangerous state determination index does not satisfy the predetermined condition (NO in step S609), the information processing apparatus 200 advances to step S615; otherwise (YES in step S609), the information processing apparatus 200 advances to step S611.

In step S611, the information processing apparatus 200 extracts determination information for a predetermined period until the dangerous state is generated, and accumulates it. In step S613, the information processing apparatus 200 determines whether to end the processing. If it is determined not to end the processing (NO in step S613), the information processing apparatus 200 advances to step S615. In step S615, the information processing apparatus 200 updates the self-vehicle traveling parameters, the peripheral vehicle traveling parameters, and the traveling environment parameters. If it is determined to end the processing (YES in step S613), the information processing apparatus 200 ends the processing.

According to this example embodiment, it is possible to efficiently collect data in a pre-dangerous state of a vehicle that is difficult to generate in the actual environment. Furthermore, since the peripheral vehicle traveling parameters of the peripheral vehicles, which readily put the self-vehicle in a dangerous state, are updated and provided, it is possible to comprehensively collect data of the dangerous state and the pre-dangerous state.

### Third Example Embodiment

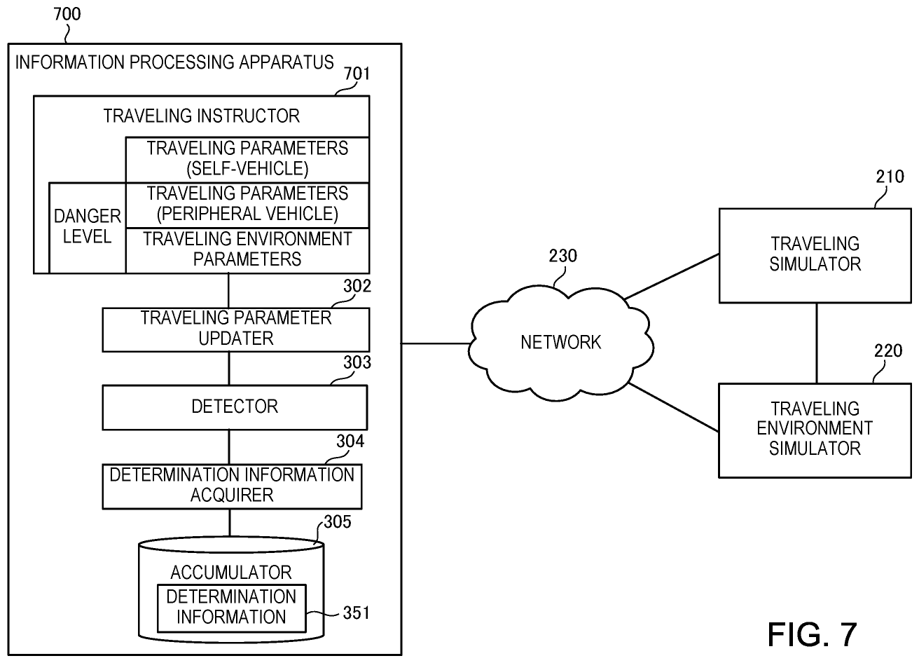

An information processing apparatus according to the third example embodiment of the present invention will be described next with reference to FIGS. 7 to 10. FIG. 7 is a block diagram for explaining the arrangement of the information processing apparatus according to this example embodiment. The information processing apparatus according to this example embodiment is different from that according to the above-described second example embodiment in that a traveling instructor provides parameters corresponding to a danger level. The remaining components and operations are similar to those in the second example embodiment. Hence, the same reference numerals denote similar components and operations, and a detailed description thereof will be omitted.

An information processing apparatus 700 includes a traveling instructor 701. The traveling instructor 701 instructs virtual traveling while providing self-vehicle traveling parameters, peripheral vehicle traveling parameters, and traveling environment parameters to a traveling simulator 210 and a traveling environment simulator 220. Furthermore, with respect to the periphery vehicle traveling parameters, the traveling instructor 701 provides, to the traveling simulator 210, the peripheral vehicle traveling parameters that readily generate a dangerous state so that a self-vehicle 201 is readily put in the dangerous state by traveling of a peripheral vehicle. With respect to the traveling environment parameters, the traveling instructor 701 provides, to the traveling environment simulator 220, the traveling environment parameters that readily generate a dangerous state so as to generate a traveling environment in which the self-vehicle 201 is readily put in the dangerous state.

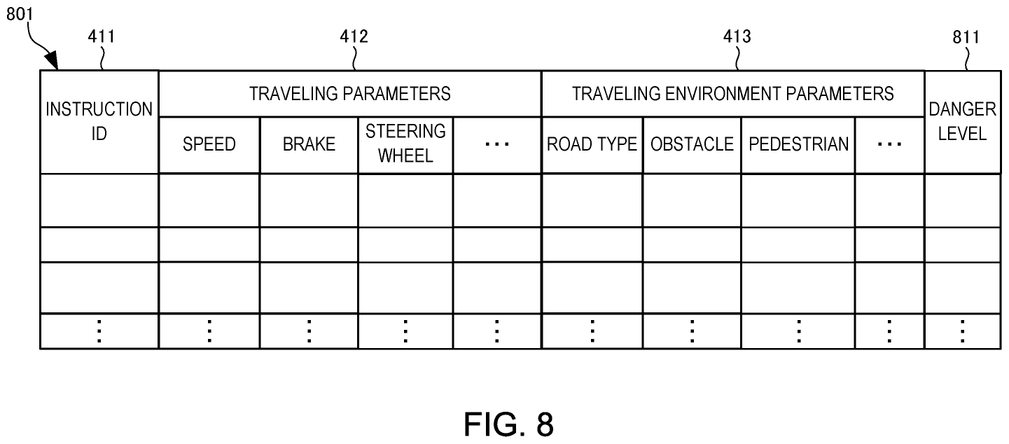

FIG. 8 is a table showing an example of a parameter table 801 provided in the information processing apparatus 700 according to this example embodiment. The parameter table 801 stores a danger level 811 in association with an instruction ID 411. The danger level 811 indicates the possibility of a dangerous state corresponding to a combination of traveling parameters 412 and traveling environment parameters 413. With reference to the parameter table 801, a traveling instructor 701 provides the peripheral vehicle traveling parameters that readily generate a dangerous state. Similarly, with reference to the parameter table 801, the traveling instructor 701 provides the traveling environment parameters that readily generate a dangerous state.

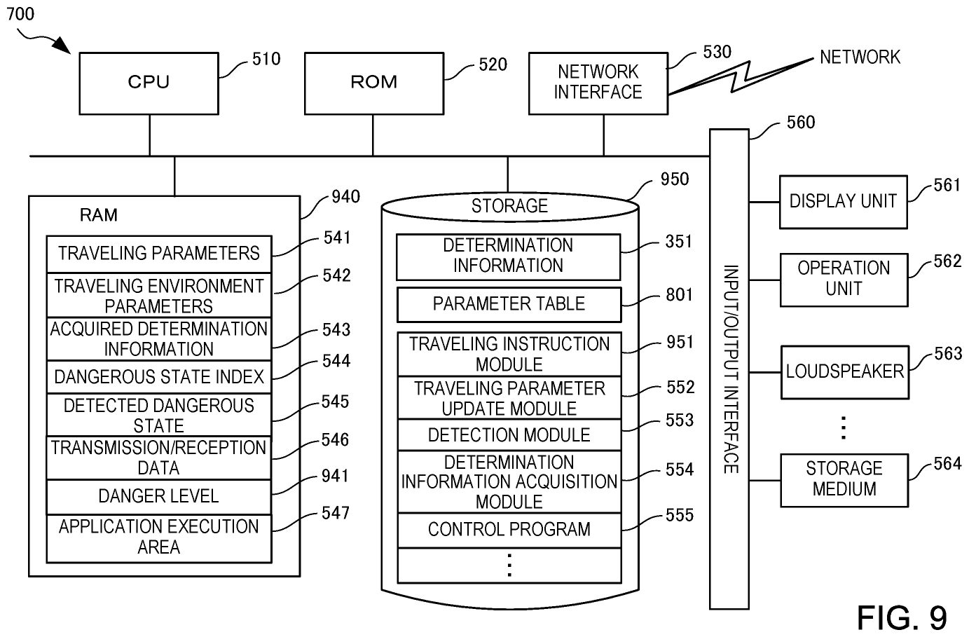

FIG. 9 is a block diagram for explaining the hardware arrangement of the information processing apparatus 700 according to this example embodiment. A CPU (Central Processing Unit) 510 is an arithmetic control processor, and implements the functional components of the information processing apparatus 700 shown in FIG. 7 by executing a program.

A RAM 940 is a random access memory used as a temporary storage work area by the CPU 510. An area to store data necessary for implementation of this example embodiment is allocated to the RAM 940. A danger level 941 is an index indicating the peripheral vehicle traveling parameters and the traveling environment parameters that readily put the self-vehicle in a dangerous state, and is loaded from, for example, the parameter table 801.

A storage 950 stores the parameter table 801. The parameter table 801 is the table, shown in FIG. 8, for managing the relationship among the instruction ID, the danger level, and the like.

The storage 950 further stores a traveling instruction module 951. The traveling instruction module 951 is a module that instructs virtual traveling while providing the peripheral vehicle traveling parameters and the traveling environment parameters that readily put the self-vehicle in a dangerous state. This module 951 is read out by the CPU 510 into an application execution area 547 of the RAM 940, and executed.

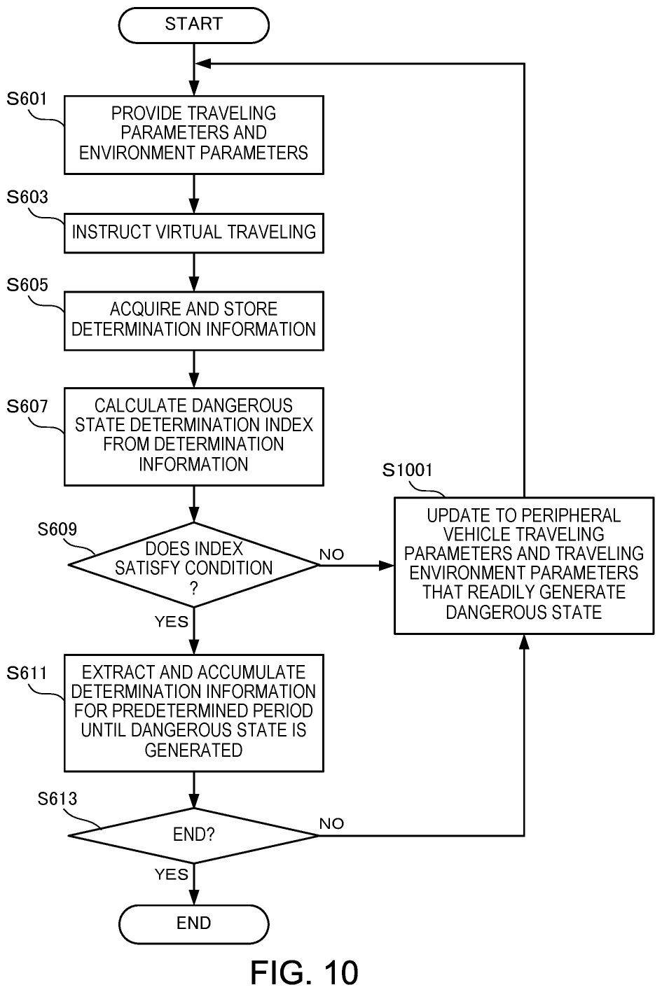

FIG. 10 is a flowchart for explaining the processing procedure of the information processing apparatus 700 according to this example embodiment. This flowchart is executed by the CPU 510 of FIG. 9 using the RAM 540, thereby implementing the functional components of the information processing apparatus 700 shown in FIG. 7. In step S1001, the information processing apparatus 700 updates the peripheral vehicle traveling parameters and the traveling environment parameters to peripheral vehicle traveling parameters and traveling environment parameters that readily generate a dangerous state. Then, the information processing apparatus 700 provides, to the traveling simulator 210, the peripheral vehicle traveling parameters that readily generate the dangerous state, and provides, to the traveling environment simulator 220, the traveling environment parameters that readily generate the dangerous state.

According to this example embodiment, since peripheral vehicle traveling parameters and traveling environment parameters that readily put the self-vehicle in a dangerous state are provided to the traveling simulator and the traveling environment simulator, it is possible to comprehensively collect data of a dangerous state and a pre-dangerous state more efficiently.

### Fourth Example Embodiment

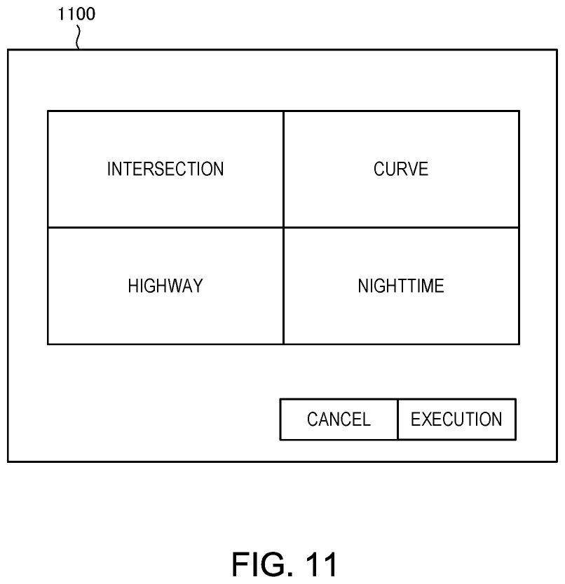

An information processing apparatus according to the fourth example embodiment of the present invention will be described next with reference to FIGS. 11 to 13. FIG. 11 is a view for explaining an example of the display screen of the information processing apparatus according to this example embodiment. The information processing apparatus according to this example embodiment is different from those according to the above-described second and third example embodiments in that a traveling parameter classifier is provided. The remaining components and operations are similar to those in the second and third example embodiments. Hence, the same reference numerals denote similar components and operations, and a detailed description thereof will be omitted.

The selection buttons of traveling parameters are displayed on a display screen 1100. The information processing apparatus classifies traveling parameters in this way. Therefore, when the user selects the selection button of a desired traveling parameter, and presses an execution button, he/she can acquire data of a dangerous state and a pre-dangerous state in a desired situation.

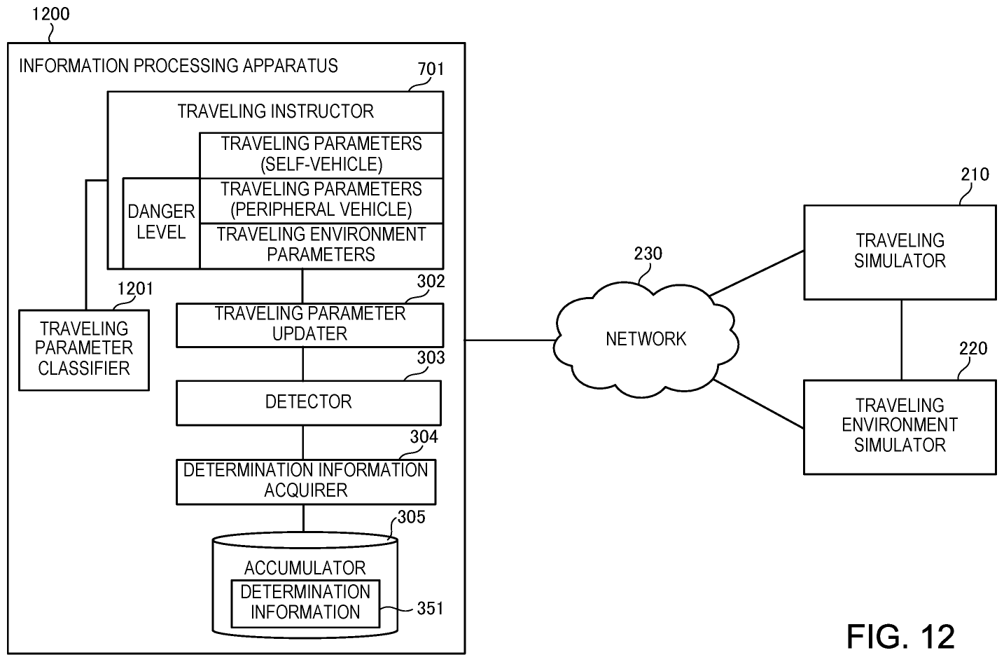

FIG. 12 is a block diagram showing the arrangement of an information processing apparatus 1200 according to this example embodiment. The information processing apparatus 1200 includes a traveling parameter classifier 1201. The traveling parameter classifier 1201 classifies, for example, self-vehicle traveling parameters. Similarly, the traveling parameter classifier 1201 classifies peripheral vehicle traveling parameters. Then, a traveling instructor 701 instructs a traveling simulator 210 and a traveling environment simulator 220 to execute virtual traveling while providing the classified traveling parameters.

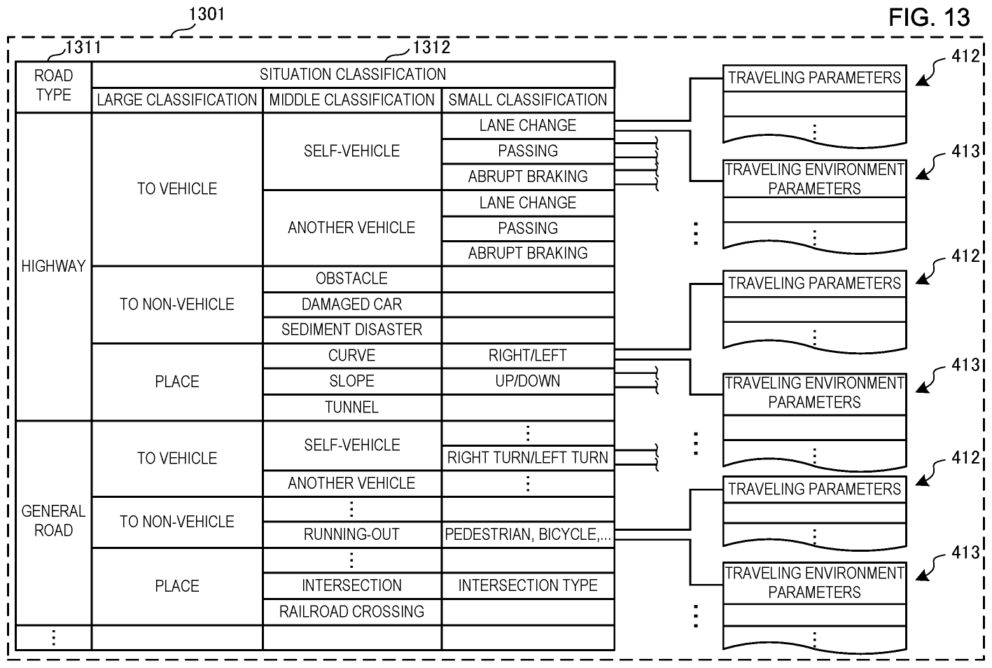

FIG. 13 is a table showing an example of a classification table provided in the information processing apparatus 1200 according to this example embodiment. A classification table 1301 may be generated by, for example, the traveling parameter classifier 1201. The classification table 1301 stores a situation classification 1312 in association with a road type 1311. The road type 1311 may include an intersection or a curve, and nighttime or daytime in addition to a highway and a general road. The situation classification 1312 is divided into a large classification, a middle classification, and a small classification. The large classification includes “to vehicle”, “to non-vehicle other than vehicle”, and “to place”. The middle classification includes “situation related to movement of self-vehicle” and “situation related to movement of another vehicle” for “to vehicle”, “obstacle”, and “curve”. The small classification includes “lane change”, “passing”, and “abrupt braking”. These classifications are linked with traveling parameters 412 and traveling environment parameters 413. Therefore, the traveling instructor 701 provides the classified traveling parameters and traveling environment parameters to the simulators with reference to the classification table 1301.

According to this example embodiment, it is possible to simulate a desired situation instead of comprehensively performing a simulation, and to collect data of a dangerous state and a pre-dangerous state in the desired situation more efficiently. Since the user can make the simulators focus on a simulation of a predetermined situation, it is possible to efficiently collect necessary data of a dangerous state and a pre-dangerous state.

### Other Example Embodiments

While the invention has been particularly shown and described with reference to example embodiments thereof, the invention is not limited to these example embodiments. It will be understood by those of ordinary skill in the art that various changes in form and details may be made therein without departing from the spirit and scope of the present invention as defined by the claims. A system or apparatus including any combination of the individual features included in the respective example embodiments may be incorporated in the scope of the present invention.

The present invention is applicable to a system including a plurality of devices or a single apparatus. The present invention is also applicable even when an information processing program for implementing the functions of example embodiments is supplied to the system or apparatus directly or from a remote site. Hence, the present invention also incorporates the program installed in a computer to implement the functions of the present invention by the computer, a medium storing the program, and a WWW (World Wide Web) server that causes a user to download the program. Especially, the present invention incorporates at least a non-transitory computer readable medium storing a program that causes a computer to execute processing steps included in the above-described example embodiments.

What is claimed is:

1. An information processing apparatus comprising:
a traveling instructor that instructs virtual traveling while providing traveling parameters to a traveling simulator that simulates traveling of at least one virtual peripheral vehicle and a virtual self-vehicle in a virtual environment; and
a detector that detects occurrence of a dangerous state for the self-vehicle in the simulation by the traveling simulator.

2. The information processing apparatus according to claim 1, further comprising:
a traveling parameter updater that updates the traveling parameters provided by said traveling instructor; and
an accumulator that acquires, from the traveling simulator, determination information for determining a pre-dangerous state before the dangerous state detected by said detector is generated, and accumulates the determination information.

3. The information processing apparatus according to claim 1, wherein said traveling instructor provides traveling parameters of the peripheral vehicle that readily generate the dangerous state.

4. The information processing apparatus according to claim 1, wherein said traveling instructor instructs a traveling environment simulator to generate a virtual traveling environment, and instructs a simulation of the traveling environment while providing traveling environment parameters.

5. The information processing apparatus according to claim 4, wherein said traveling instructor provides the traveling environment parameters that generate a traveling environment in which the dangerous state is readily generated.

6. The information processing apparatus according to claim 1, wherein said traveling instructor changes some of the traveling parameters in one dangerous state detected by said detector, which are associated with the detected dangerous state.

7. The information processing apparatus according to claim 1, wherein said traveling instructor classifies the traveling parameters, and instructs virtual traveling while providing the classified traveling parameters.

8. An information processing method, comprising:
instructing virtual traveling while providing traveling parameters to a traveling simulator that simulates traveling of at least one virtual peripheral vehicle and a virtual self-vehicle in a virtual environment; and
detecting occurrence of a dangerous state for the self-vehicle in the simulation by the traveling simulator.

9. A non-transitory computer readable medium storing a information processing program for causing a computer to execute a method, comprising:
instructing virtual traveling while providing traveling parameters to a traveling simulator that simulates traveling of at least one virtual peripheral vehicle and a virtual self-vehicle in a virtual environment; and
detecting occurrence of a dangerous state for the self-vehicle in the simulation by the traveling simulator.
